(19) United States
(12) Patent Application Publication
(10) Pub. No.: US 2014/0338737 A1
(43) Pub. Date: Nov. 20, 2014

(54) SOLAR CELL

(71) Applicant: SAMSUNG SDI CO., LTD., Yongin-si (KR)

(72) Inventors: Jung-Yup YANG, Yongin-si (KR); Jung-Gyu NAM, Yongin-si (KR)

(73) Assignee: SAMSUNG SDI CO., LTD., Yongin-si (KR)

(21) Appl. No.: 14/154,299

(22) Filed: Jan. 14, 2014

Related U.S. Application Data
(60) Provisional application No. 61/823,138, filed on May 14, 2013.

(51) Int. Cl. H01L 31/05; H01L 31/032; H01L 31/0749

(52) U.S. Cl. CPC H01L 31/05; H01L 31/0749; H01L 31/0322
USPC 136/256

(57) ABSTRACT

A solar cell including a substrate; a first electrode on the substrate; an intermediate connection layer on the first electrode, the intermediate layer including a first region and a third region; a light absorbing layer on the third region of the intermediate connection layer; and a wire on the first region of the intermediate connection,wherein a thickness of the first region of the intermediate connection layer is different from a thickness of the third region of the intermediate connection layer.

### CROSS-REFERENCE TO RELATED APPLICATION

The present application claims priority under 35 U.S.C. §119(e) to U.S. Provisional Application No. 61/823,138, filed on May 14, 2013, and entitled: “SOLAR CELL,” which is incorporated herein by reference in its entirety.

### BACKGROUND

1. Field

Embodiments relate to a solar cell.

2. Description of the Related Art

As demands on energy increase, demands on solar cells for converting sunlight energy into electrical energy have also increased. Solar cells are clean energy sources that produce electricity using the sun as an almost infinite energy source. Solar cells have come into the spotlight as a new growth engine with a high industrial growth rate every year.

### SUMMARY

Embodiments are directed to a solar cell.

Embodiments may be realized by providing a solar cell including a substrate; a first electrode on the substrate; an intermediate connection layer on the first electrode, the intermediate layer including a first region and a third region; a light absorbing layer on the third region of the intermediate connection layer; and a wire on the first region of the intermediate connection, wherein a thickness of the first region of the intermediate connection layer is different from a thickness of the third region of the intermediate connection layer.

The thickness of the first region of the intermediate connection layer may be thinner than the thickness of the third region of the intermediate connection layer.

The intermediate connection layer may further include a second region, the second region being uncovered by the light absorbing layer and the wire and being between the first region and the third region.

The second region of the intermediate connection layer may have a thickness that is about equal to the thickness of the first region of the intermediate connection layer.

The second region of the intermediate connection layer may have a thickness that is about equal to the thickness of the third region of the intermediate connection layer.

The second region of the intermediate connection layer may protect a surface of the first electrode from penetrating moisture.

The light absorbing layer may include a CIGS material.

The first electrode may include molybdenum.

The intermediate connection layer may include a MoSeₓ compound, in which x is a natural number.

The thickness of the first region of the intermediate connection layer may be about 0.1 nm to about 30 nm.

The wire may include at least one of lead, tin, copper, aluminum, silver, gold, platinum, cobalt, tantalum, titanium, and alloys thereof.

The intermediate connection layer may be continuously disposed on the first electrode.

The wire may be coupled with the first region of the intermediate connection layer by at least one of soldering, ultrasonic soldering, ultrasonic welding, silver glue, and conductive tape.

The wire may be directly on the first region of the intermediate connection layer.

The solar cell may further include a second electrode on at least one of the light absorbing layer and the third region of the intermediate connection layer.

The second electrode may be on the light absorbing layer and the third region of the intermediate connection layer.

The solar cell may further include a buffer layer between the light absorbing layer and the second electrode.

The wire may be electrically connected to the first electrode through the first region of the intermediate connection layer.

The light absorbing layer may be electrically connected to the first electrode through the third region of the intermediate connection layer.

A difference in thickness between the first region of the intermediate connection layer and the third region of the intermediate connection layer may be achieved by selectively etching a portion of the intermediate connection layer corresponding with the first region.

### BRIEF DESCRIPTION OF THE DRAWINGS

Features will become apparent to those of skill in the art by describing in detail exemplary embodiments with reference to the attached drawings in which:

FIG. 1 illustrates a sectional view of a solar cell according to an embodiment.

FIG. 2A illustrates a sectional view of a state before a third region is provided in FIG. 1.

FIG. 2B illustrates a sectional view of a state after the third region is provided in FIG. 2A.

FIG. 3 illustrates a sectional view of a solar cell according to another embodiment.

FIG. 4 illustrates a flowchart of a method of manufacturing a solar cell according to an embodiment.

FIG. 5 illustrates a graph showing resistances according to thicknesses of a first electrode layer.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art. In the drawing figures, the dimensions of layers and regions may be exaggerated for clarity of illustration.

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. In addition, when an element is referred to as being “on” another element, it can be directly on the other element or be indirectly on the other element with one or more intervening elements interposed therebetween. Also, when an element is referred to as being “connected to” another element, it can be directly connected to the other element or be indirectly connected to the other element with one or more intervening elements interposed therebetween. Hereinafter, like reference numerals refer to like elements.

FIG. 1 illustrates a sectional view of a solar cell according to an embodiment. Referring to FIG. 1, the solar cell 100 according to this embodiment may include a substrate 110, a first electrode layer 120 on the substrate 110, an alloy layer or intermediate connection layer 130 on the first electrode layer 120, and a wire 160 connected to the intermediate connection layer 130. In an implementation, the wire 160 may be directly attached or connected to the intermediate connection layer 130. A light-absorbing layer and/or a portion of a second electrode layer 150 may be formed on the intermediate connection layer 130.

The substrate 110 may be, e.g., a glass substrate, ceramic substrate, metal substrate, polymer substrate, etc. For example, the substrate 110 may be a glass substrate including alkali elements such as sodium (Na), potassium (K) and/or cesium (Cs) therein. In an implementation, the substrate 110 may be a soda-lime glass substrate. The alkali elements included in the substrate 110 may be diffused into the light-absorbing layer 140 during a process of manufacturing the solar cell 100, so as to increase a concentration of electrons in the light-absorbing layer 140, thereby advantageously improving photoelectric conversion efficiency.

The first electrode layer 120 may be made of a conductor, e.g., a metal. For example, the first electrode layer 120 may be made of a material having excellent safety at a high temperature and high electrical conductivity. The first electrode layer 120 may be formed using a material having an excellent junction property with the substrate 110 and the light-absorbing layer 140, respectively provided on and beneath the first electrode layer 120. In an implementation, the first electrode layer 120 may be made of molybdenum (Mo).

The intermediate connection layer 130 may be formed on an upper portion of the first electrode 120 and at an interface where the light-absorbing layer 140 and the first electrode layer 120 contact each other, so as to protect a surface of the first electrode layer 120. The intermediate connection layer 130 may be formed by performing a selenization process. For example, the intermediate connection layer 130 may be formed by forming the light-absorbing layer 140 on an upper portion of the first electrode layer 120, and then allowing the first electrode layer 120 to react with selenium (Se) through the selenization process. For example, the selenium (Se) may directly react with the surface of the first electrode layer 120, or may be diffused downward from an upper surface of the light-absorbing layer 140 so as to react with the surface of the first electrode layer 120, thereby forming the intermediate connection layer 130. For example, in a case where the first electrode layer 120 is made of molybdenum (Mo), the intermediate connection layer 130 may be a selenized molybdenum compound (MoSeₓ) (in which x is a natural number).

The light-absorbing layer 140 may be a layer that absorbs light so that electric charges are formed therein. The light-absorbing layer 140 may be made of a compound semiconductor, e.g., CIS, CGS or CIGS (here, C denotes copper (Cu), I denotes indium (In), G denotes gallium, and S denotes one or more of sulfur (S) and selenium (Se)). The light-absorbing layer 140 may act as a p-type semiconductor.

The second electrode layer 150 may be a conductive layer, and may act as an n-type semiconductor. For example, the second electrode layer 150 may be made of transparent conductive oxide (TCO). In an implementation, the second electrode layer 150 may be made of zinc oxide (ZnO).

Although not shown in FIG. 1, a buffer layer may be further formed between the light-absorbing layer 140 and the second electrode layer 150. The light-absorbing layer 140 formed beneath the buffer layer may act as the p-type semiconductor, and the second electrode layer 150 formed on the buffer layer may act as the n-type semiconductor, so that a p-n junction can be formed between the light-absorbing layer 140 and the second electrode layer 150. In this case, the buffer layer may have a band gap of a middle level between the light-absorbing layer 140 and the second electrode layer 150, so that a satisfactory junction may be formed between the light-absorbing layer 140 and the second electrode layer 150.

In the solar cell 100 according to the present embodiment, the intermediate connection layer 130 may include first to third regions 131, 132, and 133. The wire 160 may be on the first region 131, and the light-absorbing layer 140 and/or the second electrode layer 150 may be on the third region 133. In this case, the second region 132 may allow the first and third regions 131 and 133 to be spaced apart from each other. For example, in an intermediate step during formation of the solar cell 100, the first region 131 and the third region 133 may be covered, and the second region 132 may be exposed between the first region 131 and the third region 132. In an implementation, in the completed solar cell, the first region 131 and the third region 133 may be covered, and the second region 132 may be exposed to an encapsulant that encapsulates the solar cell. For example, the first region 131 may be covered by the wire 160, the third region may be covered by the light absorbing layer 140 and/or the second electrode 150, and the second region 132 may be a region of the intermediate connection layer 130 that corresponds with a space between the wire 160 and the light absorbing layer 140 and/or the second electrode 150. At least one of the first to third regions 131, 132, and 133 may have a thickness different from that of the others.

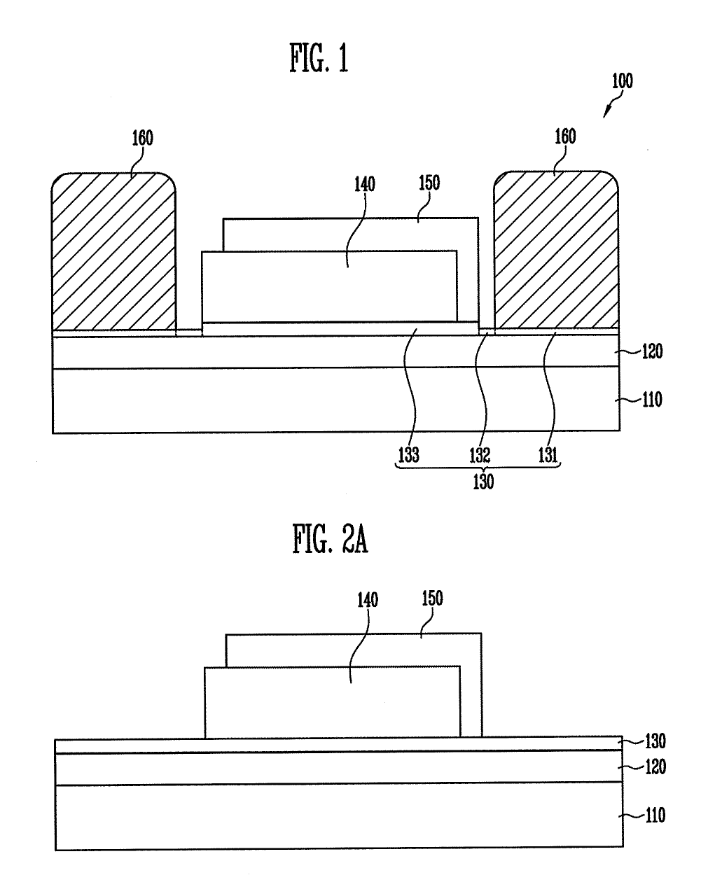

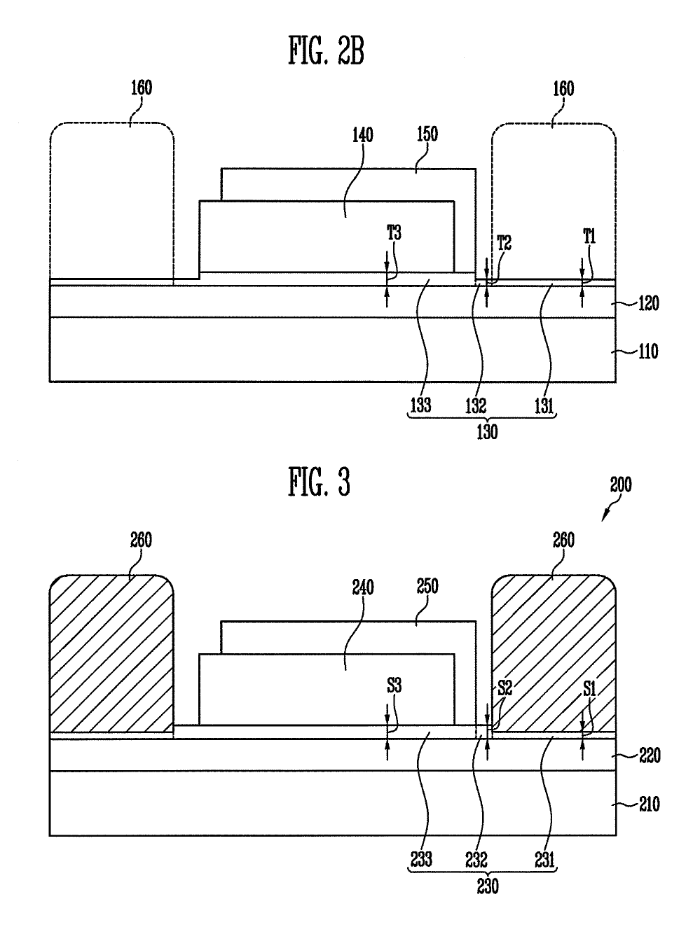

FIG. 2A illustrates a sectional view of a state before a third region is provided in FIG. 1. FIG. 2B illustrates a sectional view of a state after the third region is provided in FIG. 2A.

Referring to FIGS. 2A and 2B, the intermediate connection layer 130 may be formed on the surface of the first electrode layer 120. In this case, the light-absorbing layer 140 and/or the second electrode layer 150 may be formed on a portion of the intermediate connection layer 130. Alternatively, both the light-absorbing layer 140 and the second electrode layer 150 may not be formed on another portion of the intermediate connection layer 130, and a portion of the intermediate connection layer 130 may be exposed. The wire 160 may serve as a passage through which current generated in the solar cell 100 is transferred to the outside of the solar cell 100. The wire 160 may be made of a conductor such as metal.

The intermediate connection layer 130 on the first electrode layer 120 may have an approximately similar thickness. Subsequently, a portion of the intermediate connection layer 130 may be removed, and the wire 160 may be formed at the region having portions of the intermediate connection layer 130 removed therefrom, e.g., the intermediate connection layer 130 may be divided into the first to third regions 131, 132, and 133.

The first region 131 of the intermediate connection layer 130 may be a portion at which the wire 160 is attached to the intermediate connection layer 130. In an implementation, a region of the intermediate connection layer 130 corresponding with the first region 131 may be removed through etching. For example, the etching may be performed by any one of a mechanical method, a layer method, a plasma method, and a wet etching method. The thickness T1 of the first region 131 may be thinner than that T3 of the third region 133, and the thickness T2 of the second region 132 may be similar or about equal to that T3 of the third region 133.

In other methods of forming solar cells, an entire alloy layer or intermediate connection layer may be removed from the portion at which the wire is attached to the alloy layer or intermediate connection layer, using a knife, etc., and the first electrode layer and the wire may come in direct contact with each other. On the other hand, the process of removing the alloy layer or intermediate connection layer may necessarily be performed several times in order to remove the entire alloy layer or intermediate connection layer, and an additional cleaning process, etc., may necessarily be performed in order to remove remaining portions of the alloy layer or intermediate connection layer. As such, a plurality of processes may necessarily be performed to remove the entire alloy layer or intermediate connection layer. It may take a long period of time to perform the processes. Thus, process efficiency may be lowered.

In a case where the entire alloy layer or intermediate connection layer is removed from the first electrode layer, the wire may contact a portion of the first electrode layer, but a portion of the first electrode may be exposed as it is. Therefore, moisture or the like may penetrate into the first electrode layer, thereby lowering the electrical efficiency of the solar cell. In a case where the wire comes in direct contact with the first electrode layer, the contact portion may be pulled out in a thermal cycling test (TC test) due to the difference in thermal expansion coefficient between metal forming the wire and metal forming the first electrode layer. On the other hand, the alloy layer or intermediate connection layer may be a semiconductor layer, the alloy layer or intermediate connection layer may act as a resistor in the flow of current between the first electrode layer and the wire. Therefore, in a case where the wire is provided while maintaining the alloy layer or intermediate connection layer as it is, the electrical efficiency of the solar cell may be lowered.

In the solar cell according to the embodiments, process efficiency may be improved by simplifying the aforementioned process of removing portions of the intermediate connection layer. Further, the thickness of the intermediate connection layer may be controlled, thereby optimizing a flow of current between the first electrode layer and the wire, and the surface of the first electrode layer may be protected, thereby improving the efficiency of the solar cell.

The wire 160 may be connected to the first region 131. For example, the thickness T1 of the first region 131 may be about 0.1 nm to about 30 nm. Maintaining the thickness T1 of the first region 131 at about 0.1 nm or greater may help ensure that a plurality of processes are not necessary to achieve the desired thickness of the first region 131. Thus, the productivity of the solar cell 100 may be maintained. In addition, maintaining the thickness T1 of the first region 131 at about 0.1 nm or greater may help ensure that the first region 131 is not too thin, thereby helping to ensure that penetration of moisture or the like into the first electrode layer 120 is reduced and/or prevented. Maintaining the thickness of the first region 131 at about 30 nm or less may help ensure that the thickness of the first region 131 is not too thick, and helps ensure a smooth flow of current between the first electrode layer 120 and the wire 160. In an implementation, the thickness of the first region 131 may be about 15 nm. In a case where the thickness of the first region 131 is 15 nm, it is possible to help prevent moisture or the like from penetrating into the first electrode layer 120 and to help improve the efficiency of the flow of current between the first electrode layer 120 and the wire 160. Further, it is possible to simplify the process of removing portions of the intermediate connection layer 130, thereby optimizing the productivity and electrical characteristic of the solar cell 100.

The wire 160 may include any one selected from the group of Pb, Sn, Cu, Al, Ag, Au, Pt, Ni, Co, Ta, and Ti. The wire 160 may be attached to the first region 131 of the intermediate connection layer 130, using any one or more of soldering, ultrasonic soldering, ultrasonic welding, Ag glue, and conductive tape. In an implementation, the wire 160 may be attached to the first region 131 of the intermediate connection layer 130 using ultrasonic soldering. In a case where the wire 160 is attached to the first region 131 of the intermediate connection layer 130 using the ultrasonic soldering, a portion of solder may pass through the first region 131 and reach the first electrode layer 120 by means of ultrasonic energy, and thus the first region 131 of the intermediate connection layer 130 may have a desirably lowered resistance.

The second region 132 may be between the first and third regions 131 and 133. In an implementation, portions of the intermediate connection layer 130 corresponding with the second region 132 may be removed together with the first region 131 so as to have a thickness similar or about equal to that of the first region 131. The second region 132 may be formed on the first electrode layer 120 so as to protect the first electrode layer 120 from the penetration of moisture. In an implementation, the light-absorbing layer 140 and the second electrode layer 150 may be sequentially formed in at least a portion of the third region 133, and only the second electrode layer 150 may be formed in another portion of the third region 133.

Hereinafter, another embodiment will be described with reference to FIG. 3. Contents of this embodiment, except the following contents, are similar to those of the embodiment described with reference to FIGS. 1 to 2B, and therefore, repeated detailed descriptions may be omitted.

FIG. 3 illustrates a sectional view of a solar cell according to another embodiment. Referring to FIG. 3, the solar cell 200 according to the present embodiment may include a substrate 210, a first electrode layer 220 on the substrate 210, an intermediate connection layer 230 on the first electrode layer 220, and a wire 260 directly connected to the intermediate connection layer 230.

The intermediate connection layer 230 may include first to third regions 231, 232, and 233. The wire 260 may be connected to the first region 231, and a light-absorbing layer 240 and a second layer 250 may be formed on the third region 233. Alternatively, the light-absorbing layer 240 may be omitted, and the second electrode layer 250 may be formed on the third region 233. The second region 232 may be between the first and third regions 231 and 233, so as to allow the first and third regions 231 and 233 to be spaced apart from each other.

In the present embodiment, the first region 231 may have a thickness different from that of the second and third regions 232 and 233. For example, only an upper layer of the first region 231 of the intermediate connection layer 230 may be removed, and the thickness S1 of the first region 231 may be thinner than the thickness S2 of the second region 232 and the thickness S3 of the third region 233. The thickness S2 of the second region 232 may be approximately identical to that S3 of the third region 233.

The first region 231 may be a portion at of the intermediate connection layer 230 the wire 260 is connected to. In an implementation, the thickness S1 of the first region 231 may be about 0.1 to about 30 nm in consideration of the flow of current between the wire 260 and the first electrode layer 220, the adhesion between the first region 231 and the wire 260, etc. Maintaining the thickness S1 of the first region 231 at about 0.1 nm or greater may help ensure that the time required to remove the portions of the intermediate connection layer 230 corresponding with first region 231 is not increased. Further, maintaining the thickness S1 of the first region 231 at about 0.1 nm or greater may help ensure that the wire 160 does not come off, during the TC test, due to lowered adhesion between the first region 231 and the wire 260, which may be caused by a difference in thermal expansion coefficient between materials respectively constituting the first region 231 and the wire 260. Maintaining the thickness S1 of the first region 231 at about 30 nm or less may help ensure that the resistance between the wire 260 and the first electrode layer 220 is not increased, thereby maintaining the current efficiency of the solar cell.

In the solar cell 200 according to the present embodiment, the thickness S2 of the second region 232 may be similar or about equal to that S3 of the third region 233. Thus, the process of removing portions of the intermediate connection layer 230 may be omitted in the area corresponding with the second region 232, thereby improving the process efficiency of the solar cell. Further, only the intermediate connection layer 230 may be formed approximately on the first electrode layer 220 in the second region 232, and thus the thickness S2 of the second region 232 may be maintained thick. Accordingly, it is possible to improve the ability of protection against penetration of moisture into the first electrode layer, etc.

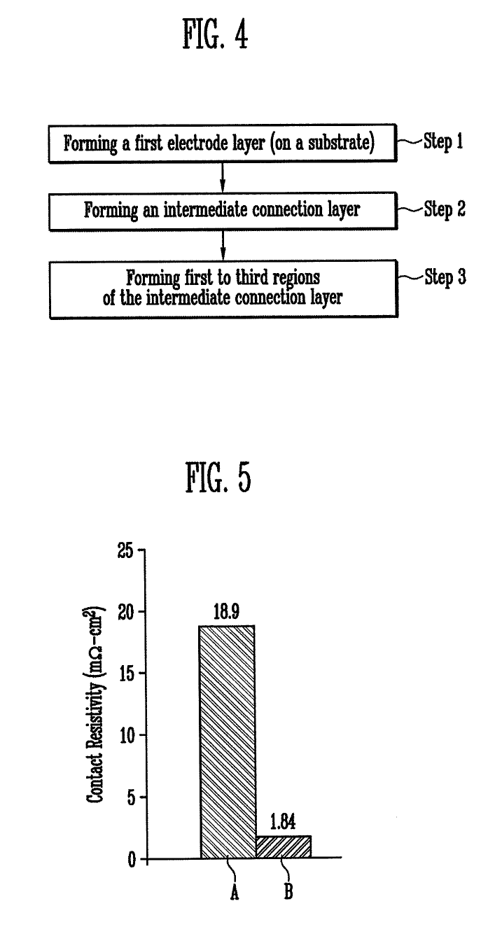

FIG. 4 illustrates a flowchart of a method of manufacturing a solar cell according to an embodiment. Referring to FIG. 4, the method according to the present embodiment may include forming a first electrode layer on a substrate (Step 1), forming an intermediate connection layer on the first electrode layer (Step 2), and forming first to third regions having different thicknesses by removing a portion of the intermediate connection layer (S3). The method may further include attaching a wire to the first region after the forming of the first to third regions (Step 3). The thickness of the first region may be thinner than that of the third region.

The method may further include forming a light-absorbing layer on a portion of the first electrode layer before the forming the intermediate connection layer on the first electrode layer (Step 2). The forming of the intermediate connection layer on the first electrode layer (Step 3) may be performed through a selenization process. For example, the substrate may include glass, the first electrode layer may include Mo, and selenium may be provided from another element, e.g., the light-absorbing layer. In this case, the intermediate connection layer formed through the selenization process may include MoSeₓ (in which X is a natural number).

In the forming of the first to third regions (Step 3), the first region may be formed by removing a portion of the intermediate connection layer. The removing of the portion of the intermediate connection layer may be performed by any one of a mechanical method, a laser method, a plasma method, and a wet etching method. The thickness of the first region may be about 0.1 to about 30 nm. The second region of the intermediate connection layer may help prevent moisture from penetrating into the first electrode layer.

The wire may serve as a passage through which current generated in the solar cell is discharged to the outside of the solar cell. For example, the wire may be made of one selected from the group of Pb, Sn, Cu, Al, Ag, Au, Pt, Ni, Co, Ta, and Ti. The wire may be attached to the first region, using any one of conductive tape, soldering, ultrasonic soldering, ultrasonic welding and Ag glue. In an implementation, the wire may be attached to the first region using ultrasonic soldering. In this case, the thickness of the first region may be about 0.1 to about 30 nm, which is thin, and thus a portion of solder may pass through the first region and reach the first electrode layer due to the ultrasonic energy. Thus, the electrical energy between the wire and the first electrode layer may be easily performed by the solder, so that resistance is decreased, thereby improving the mobility of current.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

A first electrode made of Mo was formed on a glass substrate. A light-absorbing layer made of CIG (e.g., CuGa/In or CuInGa) was formed on the first electrode. Then, a selenization process was performed on the substrate having the first electrode and the light-absorbing layer. After the selenization process was performed, Se was diffused into the light-absorbing layer, and an intermediate connection layer made of MoSe₂ was formed on a surface on the first electrode layer. The thickness of a first region to which a wire was attached at a portion where the MoSe₂ was exposed was changed as described in the following Table 1. In this case, the wire was made of conductive tape in which a conductive layer was configured with metal particles such as Ni or Ag, and the thickness of the first region was mechanically reduced using a knife. The conductive tape was attached to the first region, and the resistance of the MoSe₂ was then measured. Alternatively, as a prophetic example, the light-absorbing layer made of CIGSeS may be formed by performing a sulfurization process in order to obtain high voltage.

TABLE 1

Thickness of MoSe₂

| | 200 nm | 30 nm | 20 nm | 0.1 nm | 0 nm |
|---|---|---|---|---|---|
| Resistance | 18.9 | 1.843 | 1.84 | 1.81 | 25 |
| (mΩcm²) | | | | | |
| TC test | OK | OK | OK | OK | NG |

Table 1 shows resistances with respect to thicknesses of portions at which the wire is attached to the first region of the MoSe₂ intermediate connection layer. In addition, Table 1 shows results of a thermal cycling (TC) test. In the TC test, OK means the wire was well attached without coming off from the intermediate connection layer during the TC test, and NG means the wire came off from the intermediate connection layer during the TC test.

In Table 1, the example in which the thickness of the MoSe₂ was 200 nm was prepared by a method in which the selenization process was performed, and none of the resulting MoSe₂ intermediate connection layer was removed. In the examples in which the thickness of the MoSe₂ intermediate connection layer was 200 nm to 0.1 nm, the adhesion between the wire and the MoSe₂ intermediate connection layer was performed. Hence, adhesion between metals was not performed, but rather the adhesion between the MoSe₂ intermediate connection layer and the wire as metal. Thus, it may be seen that the result is OK in the TC test because the lowering of the adhesion, caused by a difference in (metal) thermal expansion coefficient between metals in the TC test, was minimized. On the other hand, when the thickness of the MoSe₂ intermediate connection layer was too thick, i.e., where the thickness of the MoSe₂ intermediate connection layer was 200 nm, the resistance between the wire and the first electrode layer was increased. Accordingly, it may be seen that the current efficiency was considerably lowered.

The example in which the thickness of the MoSe₂ intermediate connection layer was 0 nm was an example in which the MoSe₂ intermediate connection layer was entirely removed from the attachment portion of the wire. The wire instead came in direct contact with the first electrode layer, and thus the resistance was very low. On the other hand, it may be seen that the wire (Cu) was easily separated from the first electrode layer (Mo), during the TC test, by the difference in thermal expansion coefficient between Mo of the first electrode layer and Cu of the wire. The process of removing the MoSe₂ intermediate connection layer using the knife was performed several times in order to remove the entire MoSe₂ intermediate connection layer, and a cleaning process was additionally performed using chromic acid and/or a laser in order to remove the entire remaining MoSe₂ intermediate connection layer. In order to remove the entire MoSe₂ intermediate connection layer, the removal process was performed a plurality of times, and thus the manufacturing process lasted a long period of time. Further, it may be seen that the result of the TC test is NG. Since a portion of the first electrode layer was exposed as it is, it may be seen that moisture or the like penetrated into the first electrode layer.

When the thicknesses of the MoSe₂ intermediate connection layer were respectively 30 nm, 20 nm, and 0.1 nm, it may be seen that all the results of the TC test were OK, and the resistances were respectively 1.843, 1.84, and 1.81, which were approximately similar. For example, it may be seen that the resistances in the thickness of 0.1 to 30 nm were approximately similar, and the adhesion between the MoSe₂ intermediate connection layer and the wire was similar in the thickness of 0.1 to 30 nm. In addition, the MoSe₂ intermediate connection layer was removed so that the thicknesses of the MoSe₂ intermediate connection layer were respectively 30 nm, 20 nm, and 0.1 nm, and a portion of the MoSe₂ intermediate connection layer remained, so that the process of removing the MoSe₂ intermediate connection layer was efficiently performed.

FIG. 5 illustrates a graph showing resistances according to thicknesses of a first electrode layer.

For example, the contact resistances in a case A where the thickness of the MoSe₂ intermediate connection layer was 200 nm and a case B where the thickness of the MoSe₂ intermediate connection layer was 30 nm are shown in Table 1. Referring to FIG. 5, it may be seen that the resistance in the case A where the wire was attached without removing the MoSe₂ was approximately 10 times greater than that in the case B, where the wire was attached after portions of the MoSe₂ intermediate connection layer were removed and only 30 nm was left.

When the wire (e.g., Pb wire) was attached to the MoSe₂ intermediate connection layer having the thickness of 30 nm, an example where the attachment was performed using the conductive tape and an example where the attachment was performed using the ultrasonic soldering were compared in the following Table 2.

TABLE 2

Wire attaching method

| | Conductive tape | Ultrasonic soldering |
|---|---|---|
| Thickness of MoSe₂ | 30 nm | 30 nm |
| Resistance (mΩcm²) | 1.843 | 1.56 |
| TC test | OK | OK |

Referring to Table 2, when the thickness of the MoSe₂ was 30 nm, it may be seen that both the results in the example where the wire was attached to the MoSe₂ using the conductive tape and the example where the wire was attached to the MoSe₂ using the ultrasonic soldering were OK in the TC test. On the other hand, it may be seen that the resistance in the example where the wire was attached to the MoSe₂ using the ultrasonic soldering was lower than that in the example where the wire was attached to the MoSe₂. Without being bound by theory, it is believed that this is because a portion of solder may penetrate into the MoSe₂ by ultrasonic energy during the ultrasonic soldering, and the flow of current may be more efficiently performed by the penetrated solder.

By way of summation and review, a copper-indium-gallium-(di)selenide (CIGS) solar cell is a solar cell that may be implemented as a thin film and may not use Si. Thus, the CIGS solar cell may play an important role in spread of sunlight energy by lowering production cost of solar cells. Further, the CIGS solar cell may be thermally stable. Thus, a decrease in efficiency may not occur as time elapses. Therefore, various studies have been conducted to increase power-generating capacity of the CIGS solar cell.

The embodiments provide a solar cell having a new structure. The embodiments also provide a solar cell having improved power-generation efficiency.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A solar cell, comprising:
a substrate;
a first electrode on the substrate;
an intermediate connection layer on the first electrode, the intermediate layer including a first region and a third region;
a light absorbing layer on the third region of the intermediate connection layer; and
a wire on the first region of the intermediate connection,
wherein a thickness of the first region of the intermediate connection layer is different from a thickness of the third region of the intermediate connection layer.

2. The solar cell as claimed in claim 1, wherein the thickness of the first region of the intermediate connection layer is thinner than the thickness of the third region of the intermediate connection layer.

3. The solar cell as claimed in claim 2, wherein the intermediate connection layer further includes a second region, the second region being uncovered by the light absorbing layer and the wire and being between the first region and the third region.

4. The solar cell as claimed in claim 3, wherein the second region of the intermediate connection layer has a thickness that is about equal to the thickness of the first region of the intermediate connection layer.

5. The solar cell as claimed in claim 3, wherein the second region of the intermediate connection layer has a thickness that is about equal to the thickness of the third region of the intermediate connection layer.

6. The solar cell as claimed in claim 3, wherein the second region of the intermediate connection layer protects a surface of the first electrode from penetrating moisture.

7. The solar cell as claimed in claim 2, wherein the light absorbing layer includes a CIGS material.

8. The solar cell as claimed in claim 7, wherein the first electrode includes molybdenum.

9. The solar cell as claimed in claim 8, wherein the intermediate connection layer includes a MoSeₓ compound, in which x is a natural number.

10. The solar cell as claimed in claim 2, wherein the thickness of the first region of the intermediate connection layer is about 0.1 nm to about 30 nm.

11. The solar cell as claimed in claim 1, wherein the wire includes at least one of lead, tin, copper, aluminum, silver, gold, platinum, cobalt, tantalum, titanium, and alloys thereof.

12. The solar cell as claimed in claim 1, wherein the intermediate connection layer is continuously disposed on the first electrode.

13. The solar cell as claimed in claim 1, wherein the wire is coupled with the first region of the intermediate connection layer by at least one of soldering, ultrasonic soldering, ultrasonic welding, silver glue, and conductive tape.

14. The solar cell as claimed in claim 1, wherein the wire is directly on the first region of the intermediate connection layer.

15. The solar cell as claimed in claim 1, further comprising a second electrode on at least one of the light absorbing layer and the third region of the intermediate connection layer.

16. The solar cell as claimed in claim 15, wherein the second electrode is on the light absorbing layer and the third region of the intermediate connection layer.

17. The solar cell as claimed in claim 15, further comprising a buffer layer between the light absorbing layer and the second electrode.

18. The solar cell as claimed in claim 1, wherein the wire is electrically connected to the first electrode through the first region of the intermediate connection layer.

19. The solar cell as claimed in claim 18, wherein the light absorbing layer is electrically connected to the first electrode through the third region of the intermediate connection layer.

20. The solar cell as claimed in claim 1, wherein a difference in thickness between the first region of the intermediate connection layer and the third region of the intermediate connection layer is achieved by selectively etching a portion of the intermediate connection layer corresponding with the first region.
